(19) United States
(12) Patent Application Publication
(10) Pub. No.: US 2022/0173151 A1
(43) Pub. Date: Jun. 2, 2022

(54) CMOS IMAGE SENSOR ENCAPSULATION MODULE AND METHOD FOR FORMING SAME, AND CAMERA APPARATUS

(71) Applicant: NINGBO SEMICONDUCTOR INTERNATIONAL CORPORATION, Ningbo, Zhejiang (CN)

(72) Inventor: Yanghui XIANG, Ningbo, Zhejiang (CN)

(21) Appl. No.: 17/434,638

(22) PCT Filed: Aug. 23, 2019
(86) PCT No.: PCT/CN2019/102254

§ 371 Date: Aug. 27, 2021

(30) Foreign Application Priority Data
Feb. 27, 2019 (CN) 201910147629.1

(51) Int. Cl. H01L 27/146; H04N 5/378; H04N 5/3745

(52) U.S. Cl. CPC H01L 27/14636; H01L 27/14634; H01L 27/1464; H04N 5/37452; H01L 27/14689; H01L 27/1469; H04N 5/378; H01L 27/14643

(57) ABSTRACT

A CMOS image sensor package module, method for forming same, and imaging device. In the CMOS image sensor package module, a signal processing chip (200) and a DRAM chip (600) are bonded to a pixel circuit substrate (100). The signal processing chip (200) and the DRAM chip (600) are electrically connected by a first interconnection structure (210) and each of a readout circuit in the pixel circuit substrate (100), the signal processing chip (200) and the DRAM chip (600) is electrically connected to a second interconnection structure (220), and the second interconnection structure (220) is electrically connected to a rewiring layer (500). This structurally optimized package module allows digital image signals output from the readout circuit to be first cached in the DRAM chip (600) and then output therefrom to the signal processing chip (200) for processing. In imaging applications of the CMOS image sensor package module, this allows for faster processing of the transmitted data and digital image signals and higher image quality.

### TECHNICAL FIELD

The present invention relates to the field of image sensors and, in particular, to a CMOS image sensor package module, a method for making such a package module, and an imaging device.

### BACKGROUND

To cater to the demand for capturing scenes, a variety of contemporary devices such as notebook computers, tablet computers, smart phones and smart toys are equipped with digital cameras. Commonly used digital cameras incorporate an imaging lens for capturing an optical image and projecting it onto the surface of a photosensitive device, where filters are included to decompose the light of the image into various color components, and the various color components are sensed by pixel cells associated with the respective filters and converted into corresponding analog signals with varying strength. These analog signals are collected by circuits in the photosensitive device and converted by an analog-to-digital converter into digital signals, which are then processed by an image signal processor (ISP) and fed to, for example, a processor of a mobile phone, for further processing. The processed signals are then stored in a memory card and get ready to be used to display the image on a screen.

Currently commonly used photosensitive devices are back-illuminated complementary metal oxide semiconductor (CMOS) image sensors, which provide a wide range of advantages over CCD image sensors, including more flexible image capture, higher sensitivity, a wider dynamic range, a higher resolution, lower power consumption and better system integration. In a back-illuminated CMOS image sensor, light is incident on the back side and propagates through the photosensitive device without needing to travel through an interconnection layer of photosensitive device. This reduces loss of the light and allows each pixel cell to receive more light energy per unit time, resulting in a significant increase in image quality.

However, with increasingly demanding requirements in terms of size, image quality and the like being imposed on CMOS image sensors, still further structural improvement would be desirable for CMOS image sensor package modules.

### SUMMARY OF THE INVENTION

In view of the above-discussed problems, the present invention proposes a structurally optimized CMOS image sensor package module allowing improved quality of images captured by a CMOS image sensor employing the package module, as well as a method for forming such a package module.

According to one aspect of the present invention, there is provided a CMOS image sensor package module comprising:

a pixel circuit substrate comprising a photosensitive zone and a readout circuit zone, wherein the photosensitive zone is provided with a pixel array of the CMOS image sensor and the readout circuit zone is provided with a readout circuit, the readout circuit having circuit interconnection terminals, the pixel circuit substrate having a first surface and a second surface opposing the first surface; an a bonding layer disposed on the first surface; a signal processing chip and a DRAM chip, which are arranged side by side on the bonding layer, wherein: the signal processing chip has a first connection terminal and a second connection terminal both facing the first surface; and the DRAM chip has a third connection terminal and a fourth connection terminal both facing the first surface; a first interconnection structure that electrically connects the first and third connection terminals, wherein the first interconnection structure comprises a first connecting bump and a second connecting bump embedded in the bonding layer, and wherein the first connecting bump is brought into electrical contact with the first connection terminal, the second connecting bump brought into electrical contact with the third connection terminal, the first connecting bump brought into electrical connection to the second connecting bump; a second interconnection structure disposed in the pixel circuit substrate and in the bonding layer so as to come into electrical connection to each of the circuit interconnection terminal, the second connection terminal and the fourth connection terminal; and a rewiring layer disposed on the second surface, wherein the rewiring layer is electrically connected to the second interconnection structure.

Optionally, the first interconnection structure may further comprise an interconnection element located on the first surface, wherein the interconnection element electrically connects the first connecting bump to the second connecting bump.

Optionally, the interconnection element may comprise an interconnection wire and a first solder pad and a second solder pad located on opposing ends of the interconnection wire, wherein the first solder pad is connected to the first connection terminal via the first connecting bump, and the second solder pad is connected to the third connection terminal via the second connecting bump.

Optionally, the interconnection element may comprise an interconnection wire, wherein the interconnection wire is connected to the first connection terminal via the first connecting bump at one end and to the third connection terminal via the second connecting bump at the other end.

Optionally, the first and second connecting bumps may be integrated as a single connecting bump extending from the first connection terminal to the third connection terminal.

Optionally, the second interconnection structure may comprise a first conductive plug disposed in the pixel circuit substrate, wherein the first conductive plug electrically connects the circuit interconnection terminal to the rewiring layer.

Optionally, the circuit interconnection terminal may include a first circuit interconnection terminal and a second circuit interconnection terminal, wherein the second interconnection structure comprises two first conductive plugs to respectively electrically connect the first and second circuit interconnection terminals to the rewiring layer.

Optionally, the second interconnection structure may comprise a second conductive plug extending through the pixel circuit substrate and the bonding layer, wherein the second conductive plug electrically connects the second connection terminal to the rewiring layer.

Optionally, the second interconnection structure may comprise a third conductive plug extending through the pixel circuit substrate and the bonding layer, wherein the third conductive plug electrically connects the fourth connection terminal to the rewiring layer.

Optionally, the signal processing chip and the DRAM chip may be arranged on the first surface in the readout circuit zone.

Optionally, the rewiring layer may comprise a rewiring line and a solder pad electrically connected to the rewiring line.

Optionally, the CMOS image sensor package module may further comprise an encapsulation layer disposed on the first surface, wherein the encapsulation layer covers the signal processing chip and the DRAM chip, and fills up any gap present on the surface.

Optionally, the CMOS image sensor package module may further comprise a dummy chip located on the bonding layer, wherein the encapsulation layer also covers the dummy chip.

Optionally, it may be configured that light is incident on the pixel array from the second surface, wherein the dummy chip is arranged above the first surface in the photosensitive zone.

Optionally, the CMOS image sensor package module may be a back-illuminated CMOS image sensor.

Optionally, the bonding layer may comprise an adhesive material.

According to another aspect of the present invention, there is provided an imaging device comprising the CMOS image sensor package module as defined above.

According to yet another aspect of the present invention, there is provided a method for forming a CMOS image sensor package module, comprising the steps of: providing a pixel circuit substrate, a signal processing chip and a DRAM chip, wherein the pixel circuit substrate comprises a photosensitive zone and a readout circuit zone, wherein the photosensitive zone is provided with a pixel array of the CMOS image sensor and the readout circuit zone is provided with the readout circuit, the readout circuit having a circuit interconnection terminal, the pixel circuit substrate having a first surface and a second surface opposing the first surface, the signal processing chip having a first connection terminal and a second connection terminal, the DRAM chip having a third connection terminal and a fourth connection terminal; forming an bonding layer on the first surface and bonding the signal processing chip and the DRAM chip to the bonding layer in such a manner that each of the first, second, third and fourth connection terminals faces the first surface; forming a first interconnection structure to electrically connect the first and third connection terminals, wherein the first interconnection structure comprises a first connecting bump and a second connecting bump that are embedded in the bonding layer, and wherein the first connecting bump is brought into electrical contact with the first connection terminal, the second connecting bump brought into electrical contact with the third connection terminal, the first connecting bump brought into electrical connection to the second connecting bump; forming a second interconnection structure disposed in the pixel circuit substrate and in the bonding layer so as to come into electrical connection to each of the circuit interconnection terminal, the second connection terminal and the fourth connection terminal; and forming a rewiring layer on the second surface, wherein the rewiring layer is electrically connected to the second interconnection structure.

Optionally, the method may further comprise, prior to the formation of the bonding layer, forming an interconnection element on the first surface, wherein the interconnection element may electrically connect the first connecting bump to the second connecting bump.

Optionally, the bonding layer may be provided with an opening, in which areas of the interconnection element aligned respectively with the first and third connection terminals are exposed.

Optionally, the first and second connecting bumps may be formed using a process comprising:

placing the pixel circuit substrate with the bonding layer, the signal processing chip and the DRAM chip in an electroless plating solution containing metal ions and a reducing agent; and forming the first and second connecting bumps in the opening after elapse of a predetermined period of time, wherein the first connecting bump covers the area of the interconnection element aligned with the first connection terminal and being electrically connected to the first connection terminal, and the second connecting bump covers the area of the interconnection element aligned with the third connection terminal and thus being electrically connected to the third connection terminal.

Optionally, the interconnection element may be exposed in the opening, wherein the first and second connecting bumps are integrated as a single connecting bump extending from the first connection terminal to the connection third connection terminal.

Optionally, the first and second connecting bumps may be formed of a material including one or more of copper, nickel, zinc, tin, silver, gold, tungsten and magnesium.

Optionally, the formation of the second interconnection structure may comprise forming a plurality of conductive plugs through forming holes by performing an etching process on the second surface and through filling the holes.

Optionally, the plurality of conductive plugs may include a first conductive plug, wherein the first conductive plug is disposed in the pixel circuit substrate and electrically connects the circuit interconnection terminals to the rewiring layer.

Optionally, the plurality of conductive plugs may include a second conductive plug, wherein the second conductive plug extends through each of the pixel circuit substrate and the bonding layer and electrically connects the second connection terminal to the rewiring layer.

Optionally, the plurality of conductive plugs may include a third conductive plug, wherein the third conductive plug extends through each of the pixel circuit substrate and the bonding layer and electrically connects the fourth connection terminal to the rewiring layer.

Optionally, the method may further comprise, subsequent to the formation of the first interconnection structure and prior to the formation of the second interconnection structure, forming an encapsulation layer on the first surface, wherein the encapsulation layer covers the signal processing chip and the DRAM chip and fills up any gap present on the surface.

Optionally, the method may further comprise, subsequent to the formation of the bonding layer, bonding a dummy chip to the bonding layer, wherein the encapsulation layer also covers the dummy chip.

Optionally, the signal processing chip and the DRAM chip may be bonded in the readout circuit zone, wherein light is configured to be incident on the pixel array from the second surface, and wherein the dummy chip is bonded in the photosensitive zone.

In the CMOS image sensor package module provided in the present invention, the signal processing chip and the DRAM chip are bonded to the pixel circuit substrate in such a manner that the signal processing chip and the DRAM chip are electrically connected by the first interconnection structure and that each of the signal processing chip, the DRAM chip and the readout circuit in the pixel circuit substrate is electrically connected to the second interconnection structure, and the rewiring layer is electrically connected to the second interconnection structure. This optimized package module allows electrical interconnection among the pixel circuit substrate, the DRAM chip and the signal processing chip. Digital image signals output from the readout circuit are cached in the DRAM chip and then transferred therefrom to the signal processing chip for processing. In imaging applications of the CMOS image sensor package module, this allows for faster processing of the transmitted data and digital image signals and higher image quality.

As the provided imaging device incorporates the above CMOS image sensor package module, it has the same or similar advantages as the package module.

The above CMOS image sensor package module can be fabricated using the method provided in the present invention. In this method, the signal processing chip and the DRAM chip are bonded to the pixel circuit substrate, dispensing with the need to form a signal processing circuit of the same functionality on the substrate. Therefore, it is no more needed to expand the substrate's lateral dimension, allowing a compact overall size of the module. When compared with the wafer-level bonding, the directly bonded arrangement is simpler and allows discarding any defective one of chips sliced from, for example, the signal processing wafer or DRAM wafer. Moreover, after the bonding, the first interconnection structure is formed to electrically connect the first connection terminal of the signal processing chip and the third connection terminal of the DRAM chip, the second interconnection structure is formed to electrically connect the circuit interconnection terminals of the readout circuit, the second connection terminal of the signal processing chip and the fourth connection terminal of the DRAM chip, and the rewiring layer is formed to electrically connect the second interconnection structure. The DRAM chip can serve as a caching component of the CMOS image sensor package module and, in imaging applications, allows for faster processing of transmitted data and digital image signals and higher image quality.

### BRIEF DESCRIPTION OF THE DRAWINGS

FIG. 1 is a cross-sectional view schematically illustrating a pixel circuit substrate, a signal processing chip and a DRAM chip provided in a method for forming a CMOS image sensor package module according to an embodiment of the present invention.

FIG. 2 is a schematic cross-sectional view of a structure resulting from bonding the signal processing chip and the DRAM chip to a bonding layer in the method for forming a CMOS image sensor package module according to an embodiment of the present invention.

FIG. 3 is a schematic cross-sectional view of a structure resulting from forming a first interconnection structure in the method for forming a CMOS image sensor package module according to an embodiment of the present invention.

FIG. 4 is a schematic cross-sectional view of a structure resulting from forming a second interconnection structure in the method for forming a CMOS image sensor package module according to an embodiment of the present invention.

FIG. 5 is a schematic cross-sectional view of a structure resulting from forming a rewiring layer in the method for forming a CMOS image sensor package module according to an embodiment of the present invention.

FIG. 6 is a schematic cross-sectional view of a CMOS image sensor package module according to an embodiment of the present invention.

### IN THESE FIGURES

100: a pixel circuit substrate; 200: a signal processing chip; 600: a DRAM chip; 100a: a first surface; 100b: a second surface; 101: a first circuit interconnection terminal; 102: a second circuit interconnection terminal; 201: a first connection terminal; 202: a second connection terminal; 601: a third connection terminal; 602: a fourth connection terminal; 300: a bonding layer; 300a: an opening; 400: an encapsulation layer; 500: a rewiring layer; 210: a first interconnection structure; 211: a connecting bump; 2111: a first connecting bump; 2112: a second connecting bump; 103: an interconnection element; 111: a first conductive plug; 112: a second conductive plug; 113: a third conductive plug; 220: a second interconnection structure; and 10: a dummy chip.

### DETAILED DESCRIPTION

Existing image signal processors for CMOS image sensors are usually integrated using a system-on-chip (SoC) technique on, or wafer-level bonded (typically involving both metal bonding and oxide bonding) to, a pixel circuit substrate containing photosensitive devices. These approaches both involve high process complexity and cost. In particular, in the wafer-level bonding approach in which bonding is conducted between wafers, the handling of any possible defective die, for example, on the signal processing wafer is complicated and costly. Additionally, in digital imaging applications of the resulting CMOS image sensor packaged modules, digital signals generated in a pixel circuit (or readout circuit) in the pixel circuit substrate are directly output to, and processed by, the image signal processor and then stored in a storage unit, for example, by a mobile phone processor. Therefore, the data processing rate (e.g., frame rate) of the photosensitive device and pixel circuit is limited by that of the image signal processor or mobile phone processor, which is unfavorable to image quality. With increasingly demanding requirements in terms of size, image quality and the like being placed on CMOS image sensor package modules, still further improvement would be desirable for structures and methods for the packaging of CMOS image sensors.

Based on above insight, the present invention provides a CMOS image sensor package module, in which a signal processing chip and a DRAM chip are bonded to a pixel circuit substrate. The signal processing chip is connected to the DRAM chip by a first interconnection structure, each of a readout circuit, the signal processing chip and the DRAM chip is electrically connected to a second interconnection structure, and the second interconnection structure is electrically connected to a rewiring layer, thereby providing a package structure allowing an electrical interconnection among the pixel circuit substrate, the signal processing chip and the DRAM chip. Compared with wafer-level bonding, the separate signal processing chip tends to be more computationally powerful and thus favorable to image quality, and the bonded arrangement is simpler and allows discarding any defective one of dies after they are sliced from the wafer. Additionally, bonding the signal processing chip and the DRAM chip to the pixel circuit substrate provides a larger design margin for the pixel array substrate, helping in overall miniaturization of the package module. In imaging applications, the DRAM chip may serve as a caching component, which stores, for example, incoming image signal data and then output the data at a rate compatible with the processing speed of the signal processing chip. This allows for faster processing of the transmitted data and digital image signals and improved image quality.

CMOS image sensor package modules, fabrication methods therefor and imaging devices provided in the present invention will be described below in greater detail with reference to particular embodiments and to the accompanying drawings. Features and advantages of the invention will be more apparent from the following description. It is to be understood that the embodiments described blow are merely some particular examples embodying the present invention and are not intended to limit the scope thereof in any sense.

It is to be noted that the drawings are provided in a very simplified form not necessarily drawn to exact scale and for the only purpose of helping to explain the disclosed exemplary embodiments in a more convenient and clearer way. Throughout the figures, like reference numbers and designations indicate like elements, unless otherwise stated. Moreover, the terms “first”, “second” and so on, as used hereinafter, may be used to distinguish between similar elements without necessarily implying any particular ordinal or chronological sequence. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

Referring to FIG. 5, a CMOS image sensor package module according to an embodiment of the present invention includes a pixel circuit substrate 100 comprising a photosensitive zone I and a readout circuit zone II (although schematically illustrated in FIG. 5, they may also be otherwise defined). A pixel array of the CMOS image sensor, which is an array of photodiodes used as pixel cells, is disposed in the photosensitive zone I, and a readout circuit is contained in the readout circuit zone II. The photodiodes and readout circuit are formed in the respective zones of the pixel circuit substrate 100 using semiconductor processes. The readout circuit has circuit interconnection terminals used for the purpose of interconnection. For ease of description, according to this embodiment, the pixel circuit substrate 100 has a first surface 100a and a second surface 100b opposing the first surface 100a.

In particular, the pixel circuit substrate 100 may be a substrate on which the CMOS image sensor is fabricated. The substrate may be, for example, a silicon substrate or a silicon-on-insulator (SOI) substrate. Other examples of the substrate's material may include germanium, silicon germanium, silicon carbide, gallium arsenide, indium gallium or another III-V group compound. According to this embodiment, the CMOS image sensor is preferred to be a back-illuminated CMOS image sensor, due to its wide range of known advantages. The back-illuminated CMOS image sensor is disposed on a back side of the substrate (i.e., the side opposite to where the photodiodes are formed). Usually, a dielectric layer is deposited on the back side and then planarized and grinded to form a filtering layer (not shown) for capturing different color components of incident light and a lens layer (not shown) for increasing an amount of captured light. On a front side of the pixel circuit substrate (the side where the photodiodes and an interconnection layer are formed), there is arranged a photosensitive layer provided with a large amount of photodiodes. The photosensitive layer may contain several millions of pixel cells (or pixel units) arranged in an array. Each pixel cell includes, for example, a photodiode and a drive circuit consisting of multiple MOS transistors. In operation, light incident on the lens layer propagates through the color filtering layer and the dielectric layer and strikes pixel cells in the photosensitive layer, generating photocurrents. In the pixel circuit substrate, the multiple zones of the pixel circuit substrate are defined by their functionality, and the pixel cells are generally arranged in the photosensitive zone I that is surrounded by peripheral circuitry. Therefore, the photosensitive I and readout circuit II zones correspond to respective surface portions of the pixel circuit substrate 100. On the photosensitive layer, there is formed an interconnection layer, which may include a stack of multiple interconnection metal layers. Every two adjacent interconnection metal layers may be connected by a plug layer. The interconnection layer is configured to electrically connect the photodiodes, the drive circuit and the peripheral circuitry to enable processing of the photocurrent signals from the photodiodes. The peripheral circuitry may in particular include an analog signal processing circuit, an analog-to-digital conversion circuit, a digital logic circuit, a readout circuit and the like. The readout circuit is arranged in the readout circuit zone II. Digital image signals that have been processed in the pixel circuit substrate 100 are output from the readout circuit zone II, or other signals are transmitted therein. The output digital image signals are fed to an image signal processing (ISP) circuit or an image signal processing chip for further processing. Reference can be made to related publications for more details in the structure of the pixel array substrate. In other embodiments, the CMOS image sensor may be alternatively a front-illustrated or stacked CMOS image sensor.

In this embodiment, as an example, the surface of the pixel circuit substrate 100 where the interconnection layer is formed is defined as a first surface 100a, and the surface where the incidence of light occurs is defined as a second surface 100b. In the readout circuit zone II of the pixel circuit substrate 100, the dielectric layer, a circuit layer and the interconnection layer (optionally as well as the lens and color filtering layers, which are not shown) are sequentially stacked in a direction from the second surface 100b to the first surface 100a. The dielectric layer may be configured to provide the substrate with a planarized surface and serve as an electrical isolation layer. The circuit layer may contain the aforementioned readout circuit and may be fabricated simultaneously with the photosensitive layer in the photosensitive zone I. The interconnection layer is superimposed on the circuit layer and contains the circuit interconnection terminals of the readout circuit. The circuit interconnection terminals may include multiple terminals for different connection purposes. For example, the terminals may include a first circuit interconnection terminal 101 and a second circuit interconnection terminal 102, which are configured to connect to external chips or circuits to enable the transfer of image digital signals or other signals.

Referring to FIG. 5, in the CMOS image sensor package module according to this embodiment, a bonding layer 300 is disposed on the first surface 100a of the pixel circuit substrate 100. Examples of the material of the bonding layer 300 may include oxides or other suitable materials. For example, it may be a bonding material suitable for fusion or vacuum bonding of the signal processing chip and a DRAM chip to the first surface 100a of the pixel circuit substrate 100. Examples of the material of the bonding layer 300 may also include adhesive materials. For example, it may be a die attach film (DAF) or a dry film for gluing the signal processing and DRAM chips onto the first surface 100a of the pixel circuit substrate 100. In this embodiment, the bonding layer 300 is preferably implemented as a dry film. A dry film is a viscous photoresist material in which a polymerization reaction may take place when the material is irradiated by ultraviolet rays to produce a stable substance that adheres to the surface to which the material is applied. In this case, the chips may be bonded to a top surface of the dry film.

The signal processing chip 200 and DRAM chip 600 are arranged side by side on the bonding layer 300. The signal processing chip 200 has a first connection terminal 201 and a second connection terminal 202, and the DRAM chip 600 has a third connection terminal 601 and a fourth connection terminal 602. In order to interconnect with the pixel circuit substrate 100, all the terminals (which may be implemented as contact pads) of the signal processing chip 200 and the DRAM chip 600 are preferably configured to face the first surface 100a of the pixel circuit substrate 100. In a preferred embodiment, the signal processing chip 200 and the DRAM chip 600 are both arranged in the readout circuit zone II of the pixel circuit substrate 100, in order to avoid exerting any adverse impact on the photosensitive zone I. However, the present invention is not so limited, because each of the chips may also be arranged at any other location of the first surface 100a, as long as the propagation of incident light to the pixel array in the photosensitive zone is not hindered.

In particular, the signal processing chip 200 may be an image signal processor (ISP) or a digital signal processor (DSP). In the former case, it can perform a series of processing procedures on output data from the pixel circuit substrate 100, such as automatic exposure control (AEC), automatic gain control (AGC), automatic white balance (AWB), color calibration, lens shading, gamma correction, defective pixel concealment, automatic black level calibration, etc. Dynamic random-access memory (DRAM), a common type of system memory, uses capacitors to store data and must be refreshed at regular intervals. As DRAMs will lose stored data when not refreshed regularly, so they can be used as system cache memories. According to this embodiment, one intended use of the DRAM chip 600 that is arranged in the CMOS image sensor package module and is connected to both the signal processing chip 200 and the pixel circuit substrate 100 is to store images captured by a high-speed imaging device that incorporates the CMOS image sensor package module (e.g., a mobile phone camera) and output them at an optimal rate for an input interface depending on the system design.

Both the signal processing chip 200 and the DRAM chip 600 may be separately designed and fabricated (in comparison with the case of a signal processing circuit that is integrated on the pixel circuit substrate). In particular, they may be unpackaged dies (rather than unsingulated dies on wafers). Compared with a signal processing circuit integrated on the pixel circuit substrate, the bonded signal processing chip is more computationally powerful and allows for better image quality. For example, when used in a camera-equipped device such as a mobile phone, the separate signal processing chip may be customized by the chip manufacturer exactly according to the specifications of the mobile phone manufacturer. This helps to achieve a better fit with other components of the camera and allows for a reduced lateral dimension of the pixel circuit substrate and thus a reduced overall size of the package module. It would be appreciated that while the description of this embodiment focuses on a CMOS image sensor package module including the pixel circuit substrate 100 and the signal processing chip 200 and the DRAM chip 600 arranged on the first surface 100a of the pixel circuit substrate 100, this does not mean that the CMOS image sensor package module according to this embodiment includes only those components. Rather, one or more other chips (e.g., an analog signal processing chip, an analog-to-digital conversion chip, a logic chip, etc.) or devices (e.g., a power device, a bipolar device, a resistor, a capacitor, etc.), including those well known in the art and associated connecting elements, may be also arranged/bonded to the pixel circuit substrate 100.

According to this embodiment, the CMOS image sensor package module further includes a first interconnection structure 210 for electrically connecting the first connection terminal 201 of the signal processing chip 200 and the third connection terminal 601 of the DRAM chip 600. Specifically, the first interconnection structure 210 includes a connecting bump 211 embedded in the bonding layer 300, which is brought into electrical contact with both the first connection terminal 201 of the signal processing chip 200 and the third connection terminal 601 of the DRAM chip 600. Referring to FIG. 5, in one embodiment of the present invention, the connecting bump 211 is a monolithic metal bump. However, the present invention is not so limited. FIG. 6 is a schematic cross-sectional view of the CMOS image sensor package module according to an embodiment of the present invention. Referring to FIG. 6, in this embodiment, the first interconnection structure 210 includes a first connecting bump 2111 embedded in the bonding layer 300 and a second connecting bump 2112 also embedded in the bonding layer 300. The first connecting bump 2111 is brought into electrical contact with the first connection terminal 201, and the second connecting bump 2112 is brought into electrical contact with the third connection terminal 601. The first connecting bump 2111 is thus brought into electrical connection to the second connecting bump 2112. Both the first and second connecting bumps 2111, 2112 may be metal bumps formed by electroplating or electroless plating. Therefore, the first and second connecting bumps 2111, 2112 may be arranged in the bonding layer 300 either as separate elements connected to the respective first and third connection terminals 201, 601 or as a unitary single-piece connecting bump that extends from the first connection terminal 201 to the third connection terminal 601 so as to connect both the first and third connection terminals 201, 601, such as the connecting bump 211 shown in FIG. 5. The first and second connecting bumps 2111, 2112 may be formed of a material including one or more of copper, nickel, zinc, tin, silver, gold, tungsten and magnesium.

Referring to FIG. 5 (or 6), in an optional embodiment, the first interconnection structure 210 may further include an interconnection element 103 disposed on the first surface 100a of the pixel circuit substrate 100. The interconnection element 103 may be formed on the first surface 100a prior to the formation of the bonding layer 300. The first and second connecting bumps 2111, 2112 may be so formed in the bonding layer 300 as to both come into contact with the interconnection element 103 and thus be brought into electrical connection to each other by the interconnection element 103. According to this embodiment, the interconnection element 103 may be a conductive element arranged on the first surface 100a of the pixel circuit substrate 100 in a passive or active manner. In an optional embodiment, the interconnection element 103 may be also electrically connected to the circuit interconnection terminals of the readout circuit in the pixel circuit substrate 100.

Further, the interconnection element 103 may include an interconnection wire formed on the first surface 100a, which is connected to the first connection terminal 201 via the first connecting bump 2111 at one end and to the third connection terminal 601 via the second connecting bump 2112 at the other end. However, the present invention is not so limited. In another embodiment, the interconnection element may include an interconnection wire and first and second solder pads located on opposing ends of the interconnection wire, which are all formed on the first surface 100a. The first solder pad may be connected to the first connection terminal 201 of the signal processing chip 200 via the first connecting bump 2111, and the second solder pad may be connected to the third connection terminal 601 of the DRAM chip 600 via the second connecting bump 2112.

Referring to FIG. 5 (or 6), the CMOS image sensor package module according to this embodiment further includes a second interconnection structure 220 disposed in the pixel circuit substrate 100 and in the bonding layer 300 so as to connect the readout circuit in the pixel circuit substrate 100 to both the signal processing chip 200 and the DRAM chip 600. Specifically, the second interconnection structure 220 is electrically connected to all the circuit interconnection terminals of the readout circuit (including the first circuit interconnection terminal 101 and the second circuit interconnection terminal 102 in the illustrated embodiment), the second connection terminal 202 of the signal processing chip 200 and the fourth connection terminal 602 of the DRAM chip 600. With the DRAM chip 600 being interconnected with the signal processing chip 200 by the first interconnection structure 210, the first and second interconnection structures 210, 220 in the CMOS image sensor package module according to this embodiment enable interconnection of the DRAM chip 600 with any of the signal processing chip 200 and the pixel circuit substrate 100. This entails an optimized package structure, in which depending on a system's design of transmitted signals, the CMOS image sensor package module, when used in, for example, capturing images, can cache output digital image signals from the readout circuit in the DRAM chip and then transfer them from the DRAM chip to the signal processing chip for processing. In this way, the data and digital image signals can be processed at a higher speed, and improved image quality can be obtained.

The second interconnection structure 220 may have an end (or electrical contact) extending up to the second surface 100b to rewire a signal terminal connected to it. Referring to FIG. 5, the CMOS image sensor package module according to this embodiment further includes a rewiring layer 500 (or redistribution layer (RDL)), which is disposed on the second surface 100b so as to come into electrical connection to the second interconnection structure 220. The rewiring layer 500 may include a rewiring line and a solder pad (I/O pad) electrically connected to the rewiring line. In order to avoid exerting any adverse impact on the incident light in the photosensitive zone I, the rewiring layer 500 is preferably arranged in a peripheral area of the second surface 100b of the pixel circuit substrate 100.

The second interconnection structure 220 may include two or more electrical contacts, electrical connection features and electrical connection wires formed therebetween in the pixel circuit substrate 100 and the bonding layer 300. According to one particular embodiment of the present invention, the second interconnection structure may include a first conductive plug 111 arranged in the pixel circuit substrate 100. The first conductive plug 111 is brought in electrical contact with one circuit interconnection terminal of the readout circuit (e.g., the first circuit interconnection terminal 101 or second circuit interconnection terminal 102 in the illustrated embodiment) at one end, and the other end of first conductive plug 111 may face the second surface 100b and come into electrical connection to the rewiring layer 500. According to one embodiment of the present invention, the second interconnection structure may include a second conductive plug 112. The second conductive plug 112 is brought in electrical contact with the second connection terminal 202 of the signal processing chip 200 at one end, and the other end of the second conductive plug 112 may face the second surface 100b and come into electrical connection to the rewiring layer 500. According to one embodiment of the present invention, the second interconnection structure may include a third conductive plug 113. The third conductive plug 113 is brought in electrical contact with the fourth connection terminal 602 of the DRAM chip 600 at one end, and the other end of the third conductive plug 113 may face the second surface 100b and come into electrical connection to the rewiring layer 500. Referring to FIG. 5 (or 6), in the illustrated embodiment, the second interconnection structure 220 includes all the first conductive plug 111, second conductive plug 112 and third conductive plug 113, as described above. Additionally, two or more first conductive plugs 111 may be provided to connect respective circuit interconnection terminals of the readout circuit. According to this embodiment, the second interconnection structure 220 includes two first conductive plugs 111, which respectively electrically connect the first and second circuit interconnection terminals 101, 102 to the rewiring layer 500.

It is to be noted that the rewiring layer 500 is shown in the figures only by way of example, and in some other exemplary embodiments, it may be connected to the individual conductive plugs (or electrical connection features) of the second interconnection structure 220. Each of the second interconnection structure 220 and the rewiring layer 500 as well as the electrical connections therebetween may be designed according to the requirements of the circuit's intended functionality, without being limited as shown in the figures.

The CMOS image sensor package module may further include an encapsulation layer 400 disposed on the first surface 100a of the pixel circuit substrate 100 so as to cover the signal processing chip 200 and the DRAM chip 600, and fill up any gap on the first surface 100a (e.g., those above the exposed surfaces of the first interconnection structure 210 and the bonding layer 300) and thus protect, from the side of the first surface 100a, the signal processing chip 200, the DRAM chip 600 and the exposed first interconnection structure 210 and bonding layer 300. The encapsulation layer 400 may be, for example, a plastic material that can be softened or flow in a molding process for forming it into a desired shape. The material of the encapsulation layer 400 may undergo a chemical reaction to crosslink and solidify. As an example, the material of the encapsulation layer 400 may include at least one thermosetting resin, such as a phenolic, urea-formaldehyde, formaldehyde-based, epoxy or unsaturated, polyurethane or polyimide. For example, it may be selected as an epoxy resin. In the encapsulation layer 400, one or more of various fillers and additives (e.g., curing agents, modifiers, mold release agents, thermal color agents, flame retardants, etc.) may be added.

Usually, in the first surface 100a of the pixel circuit substrate 100, a relatively large portion is in the photosensitive zone I, while a relatively small portion is in the peripheral circuitry zone. For this reason, in order for an optimized package to be obtained, a dummy chip 10 may be bonded to the bonding layer 300. In this case, the encapsulation layer 400 may also cover the dummy chip 10. In the illustrated embodiment, the dummy chip 10 may be bonded above the first surface 100a in the photosensitive zone I of the pixel circuit substrate 100. It is to be understood that the dummy chip 10 is bonded in the photosensitive zone I on the side opposite to that where light incidence occurs. In this embodiment, it is configured that light is incident on the second surface 100a. The dummy chip may be, for example, a silicon chip. Depending on the actual conditions of the pixel circuit substrate 100 and a chosen dummy chip size, one or more such dummy chips may be bonded in the photosensitive zone I. According to this embodiment, the dummy chip 10 helps in controlling warpage of the package module.

In the CMOS image sensor package module according to this embodiment, the signal processing chip 200 and the DRAM chip 600 are both integrated on the pixel circuit substrate 100, and every two of the three are interconnected. Such a structurally optimized package module allows digital image signals output from the readout circuit to be first cached in the DRAM chip 600 and then output therefrom at an optimal rate for the signal processing chip 200 through the interconnection between the DRAM chip 600 and the signal processing chip 200. The caching function of the DRAM enables full operation of the CMOS image sensor, which can mitigate the problems with existing mobile phones, including slow continuous shooting, unsatisfactory video quality and a low video frame rate. With the DRAM caching, a user can capture a slow-motion video at 960 fps with his/her mobile phone or images of a high-speed moving object with reduced rolling shutter distortion. Therefore, it provides for improved imaging performance and higher image quality.

In an embodiment of the present invention, there is also provided a method for forming a CMOS image sensor package module. This method can be used to make the CMOS image sensor package module as defined above.

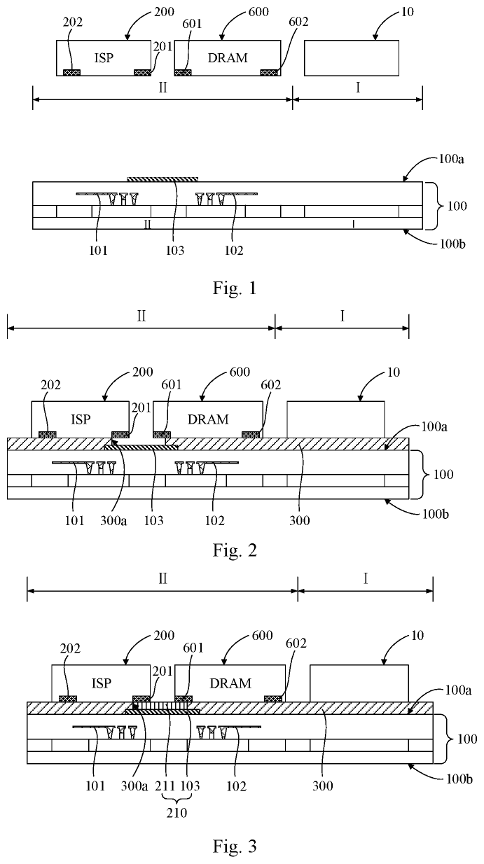

FIG. 1 is a cross-sectional view schematically illustrating a pixel circuit substrate, a signal processing chip and a DRAM chip provided in the method for forming a CMOS image sensor package module according to an embodiment of the present invention. Referring to FIG. 1, in a first step in the method according to this embodiment, the pixel circuit substrate 100, the signal processing chip 200 and the DRAM chip 600 are provided. The pixel circuit substrate 100 comprises a photosensitive zone I containing a pixel array of the CMOS image sensor and a readout circuit zone II containing a readout circuit. The pixel circuit substrate 100 has a first surface 100a and a second surface 100b opposing the first surface 100a. The signal processing chip 200 has a first connection terminal 201 and a second connection terminal 202, and the DRAM chip 600 has a third connection terminal 601 and a fourth connection terminal 602. The CMOS image sensor may be, for example, a back-illuminated one in which incident light may propagate to photodiodes in the pixel array through either the first surface 100a or second surface 100b of the pixel circuit substrate 100. In the illustrated embodiment, it may be configured that incident light propagates through the second surface 100b to the photodiodes in the pixel array.

Reference can be made to the above description made in connection with the CMOS image sensor package module for more details in the features of the pixel circuit substrate 100, the signal processing chip 200 and the DRAM chip 600. Moreover, in the first step, one or more dummy chips 10 may be further provided and bonded to the pixel circuit substrate 100 at location(s) determined according to where the signal processing chip 200 and the DRAM chip 600 are arranged, in order to control warpage of the whole package module.

In this embodiment, before the signal processing chip 200 and the DRAM chip 600 are bonded to the pixel circuit substrate 100, an interconnection element 103 may be formed on the first surface 100a as an optional member for subsequent interconnection of the signal processing chip 200 and the DRAM chip 600. Moreover, in the case of utilizing an electroplating or electroless plating process to create an electrical connection between the signal processing chip 200 and the DRAM chip 600, the interconnection element 103 may serve as a seed layer. The interconnection element 103 may be a conductive element arranged on the first surface 100a of the pixel circuit substrate 100 in a passive or active manner. In an optional embodiment, the interconnection element 103 may be also electrically connected to the circuit interconnection terminals of the readout circuit in the pixel circuit substrate 100.

The interconnection element 103 may assume one of multiple forms. According to one embodiment of the present invention, the interconnection element 103 is an interconnection wire formed on the first surface 100, for example, by depositing a metal layer on the first surface 100a and then patterning the metal layer. According to another embodiment of the present invention, the interconnection element 103 includes an interconnection wire and first and second solder pads located on opposing ends of the interconnection wire, and is connected to the signal processing chip 200 and the DRAM chip 600 through the first and second solder pads, respectively.

FIG. 2 is a schematic cross-sectional view of a structure resulting from bonding the signal processing chip and the DRAM chip to a bonding layer in the method according to an embodiment of the present invention. Referring to FIG. 2, in a second step of the method, the bonding layer 300 is formed on the first surface 100a of the pixel circuit substrate 100, and the signal processing chip 200 and the DRAM chip 600 are bonded to the bonding layer 300. All the first and second connection terminals 201, 202 of the signal processing chip 200 and the third and fourth connection terminals 601,602 of the DRAM chip 600 face the first surface 100a. The signal processing chip 200 and the DRAM chip 600 may be bonded to the pixel circuit substrate 100 by bonding or gluing. In other words, the bonding layer 300 may be either a bonding or adhesive material.

The signal processing chip 200 and the DRAM chip 600 may be bonded to the pixel circuit substrate 100 in a peripheral area, such as the readout circuit zone II. Moreover, the one or more dummy chips 10 may be bonded to the first surface 100a in the photosensitive zone I. In an alternative embodiment, the signal processing chip 200 and the DRAM chip 600 may be interconnected by the interconnection element 103. Preferably, the signal processing chip 200 and the DRAM chip 600 are so bonded that the first connection terminal 201 and the third connection terminal 601 are arranged adjacent to each other with both located on the interconnection element 103.

Additionally, in this embodiment, prior to the bonding the signal processing chip 200 and DRAM chip 600, one or two openings 300a may be formed in the bonding layer 300 in which at least an area (or part thereof) of the interconnection element 103 aligned with the first connection terminal 201 and an area (or part thereof) of the interconnection element 103 aligned with the third connection terminal 601 are exposed. In other words, it is possible to form two separate small openings 300a in which the aforementioned respective areas of the interconnection element 103 (for examples, these areas may correspond to the respective solder pads of the interconnection element 103) are exposed, or to form only one opening 300a in which the whole interconnection element 103 is exposed. The opening(s) 300a is/are to be subsequently filled to form a first interconnection structure that electrically connects the DRAM chip 600 and the signal processing chip 200. Optionally, the opening(s) 300a may be formed by depositing the material of the bonding layer 300 only on predetermined portion(s) of the interconnection element 103 so that the interconnection element 103 is exposed in the bonding layer 300. In an alternatively embodiment, the material of the bonding layer 300 may be deposited over the entire interconnection element 103 and then partially removed, for example, by a dry etching process, thus resulting in the formation of the opening(s) 300a.

FIG. 3 is a schematic cross-sectional view of a structure resulting from forming a first interconnection structure in the method according to an embodiment of the present invention. Referring to FIG. 3, in a third step of the method, the first interconnection structure 210 that electrically connects the first and third connection terminals 201, 601 is formed. The first interconnection structure 210 includes a first connecting bump embedded in the bonding layer 300 and a second connecting bump also embedded in the bonding layer 300. The first connecting bump is brought into electrical contact with the first connection terminal 201, and the second connecting bump is brought into electrical contact with the third connection terminal 601. The first connecting bump is electrically connected to the second connecting bump. In the illustrated embodiment, the entire interconnection element 103 is exposed in the opening 300a, and the first and second connecting bumps are integrated as a single connecting bump 211 that extends from the first connection terminal 201 to the third connection terminal 601. It would be appreciated that first and second connecting bumps may also be provided as separate bumps, as shown in FIG. 6.

As shown in FIG. 3, the connecting bump 211 is formed in the opening 300a. In particular, it may be formed using an electroplating or electroless plating process. In this case, the interconnection element 103 may serve as a seed layer for the electroplating or electroless plating process. As an example, the electroless plating process may include the steps of: immersing the pixel circuit substrate 100 with the bonding layer 300 to which the signal processing chip 200 and the DRAM chip 600 are bonded and in which the opening 300a is formed in a solution containing metal ions (e.g., a electroless plating solution for plating of silver, nickel, copper or the like); reducing the metal ions with a potent reducing agent to form the element metal that precipitates in the opening 300a; and allowing the reaction to proceed for a period of time until the metal forms the first and second connecting bumps (in the illustrated embodiment, the first and second connecting bumps resulting from the electroless plating reaction is integral and can be considered as a single connecting bump, i.e., the connecting bump 211 as shown in FIG. 3). The first connecting bump covers the area of the interconnection element 103 aligned with the first connection terminal 201, thus the first connecting bump is electrically connected to the first connection terminal 201. The second connecting bump covers the area of the interconnection element 103 aligned with the third connection terminal 601, thus the second connecting bump is electrically connected to the third connection terminal 601. In addition to the first and second connecting bumps, the interconnection element 103 may also be part of the first interconnection structure 210.

Electrically connecting the first connection terminal 201 of the signal processing chip 200 and the third connection terminal 601 of the DRAM chip 600 by the first and second connecting bumps formed on the interconnection element 103, respectively, eliminates the need for wire bonding or rewiring in the pixel circuit substrate and thus allows for a compactor size of the package structure while almost exerting no adverse impact on the photosensitive layer or peripheral circuitry in the pixel circuit substrate 100, thus making the package module more reliable.

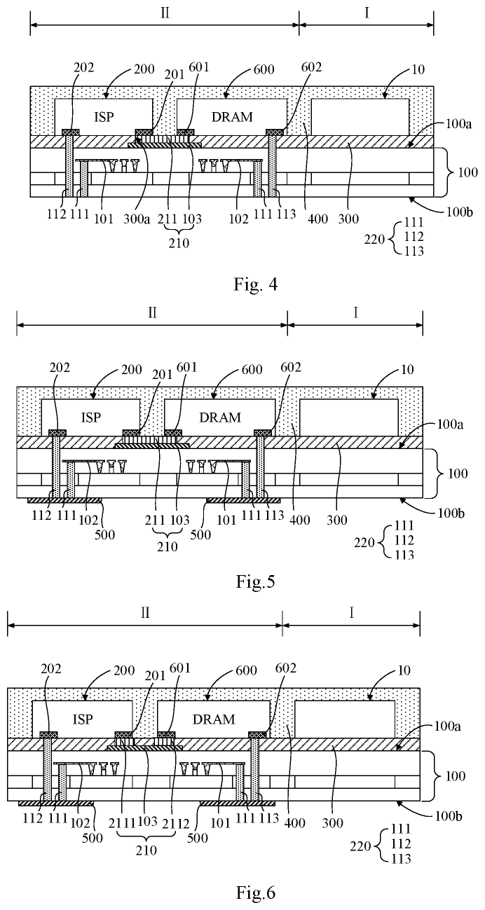

FIG. 4 is a schematic cross-sectional view of a structure resulting from forming a second interconnection structure in the method according to an embodiment of the present invention. Referring to FIG. 4, in a fourth step of the method, a second interconnection structure 220 is formed, which is disposed in the pixel circuit substrate 100 and in the bonding layer 300 and electrically connected all the circuit interconnection terminals of the readout circuit, the second connection terminal 202 of the signal processing chip 200 and the fourth connection terminal 602 of the DRAM chip 600.

In the illustrated embodiment, in order to protect the signal processing chip 200 and the DRAM chip 600 bonded to the pixel circuit substrate 100 against external factors (e.g., moisture, oxygen, vibration, shock, erosion, etc.) and ensure firm bonding, subsequent to the formation of the first interconnection structure 210 and prior to the formation of the second interconnection structure 220, the method may further include forming an encapsulation layer 400 on the first surface 100a. The encapsulation layer 400 may cover the signal processing chip 200 and the DRAM chip 600 and fill up any gap present on the first surface 100a. That is, the encapsulation layer 400 may also cover any exposed portion of the bonding layer 300 and the first interconnection structure 210. Examples of suitable materials for the encapsulation layer 400 may include: inorganic insulating materials, such as silicon oxide, silicon nitride, silicon carbide, silicon oxynitride, etc.; thermoplastic resins, such as polycarbonate, polyethylene terephthalate, polyethersulfone, polyphenylether, polyamides, polyetherimides, methacrylic resins, cyclic polyolefin based resins, etc.; thermosetting resins, such as epoxy resins, phenolic resins, urea-formaldehyde resins, formaldehyde-based resins, polyurethanes, acrylic resins, vinyl ester resins, imide based resins, urea resins, melamine resins, etc.; and organic insulating materials, such as polystyrene, polyacrylonitrile, etc. The encapsulation layer 400 may be formed using, for example, a chemical vapor deposition process or an injection molding process. The formation of the encapsulation layer 400 may further involve, for example, a planarization process resulting in a flat top surface of the encapsulation layer, which can serve as a support surface during the subsequent formation of conductive plugs and a rewiring layer.

In addition, in order to control warpage of the package module, the one or more dummy chip 10 may be bonded to the bonding layer 300 subsequent to the formation of the bonding layer 300 and prior to the formation of the encapsulation layer 400. In this case, the encapsulation layer 400 may also cover the dummy chips 10. As an example, the signal processing chip 200 and the DRAM chip 600 may be bonded to the pixel circuit substrate 100 both in the readout circuit zone, and it may be configured that incident light propagate through the second surface 100b to the pixel array. Moreover, the dummy chips 10 may be bonded to the pixel circuit substrate 100 in the photosensitive zone.

The second interconnection structure 220 may include two or more electrical contacts, electrical connection features and electrical connection wires therebetween in the pixel circuit substrate 100 and the bonding layer 300. In the illustrated embodiment, the formation of the second interconnection structure 220 may involve forming several conductive plugs using a method including forming several holes by performing an etching process on the side of the second surface 100b and filling the holes (with one or more conductive materials such as metals). Optionally, the conductive plugs may include a first conductive plug 111 that is situated in the pixel circuit substrate 100 and electrically connects the circuit interconnection terminals of the readout circuit. Optionally, the conductive plugs may include a second conductive plug 112 that electrically connects the second connection terminal 202 of the signal processing chip 200 and/or a third conductive plug 113 that electrically connects the fourth connection terminal 602 of the DRAM chip 600. Both the second and third conductive plug 112, 113 may extend through the pixel circuit substrate 100 and the bonding layer 300. Further, each conductive plug may have an end that is exposed at the second surface 100b and ready for electrical connection to the subsequently formed rewiring layer. These conductive plugs may also be formed using any other suitable known method.

Referring to FIG. 4, in the illustrated embodiment, the plurality of conductive plugs include all the first conductive plug 111 electrically connected to the circuit interconnection terminals of the readout circuit (e.g., the first circuit interconnection terminal 101 and second circuit interconnection terminal 102 as shown in FIG. 4), the second conductive plug 112 electrically connected to the second connection terminal 202 of the signal processing chip 200, and the third conductive plug 113 electrically connected to the fourth connection terminal 602 of the DRAM chip 600.

FIG. 5 is a schematic cross-sectional view of a structure resulting from forming a rewiring layer in the method according to an embodiment of the present invention. Referring to FIG. 5, after the second interconnection structure 220 is formed, the method further includes a fifth step, in which the rewiring layer 500 is so formed on the second surface 100b of the pixel circuit substrate 100 as to come into electrical connection to the second interconnection structure 220.

In particular, the rewiring layer 500 may be formed on a dielectric layer on the second surface 100b of the pixel circuit substrate 100 and brought into contact with the plurality of conductive plugs of the second interconnection structure 220, thus coming into electrical connection to the second interconnection structure 220. The rewiring layer 500 may be formed by, for example, patterning a metal layer deposited on the second surface 100b of the pixel circuit substrate 100 using a physical vapor deposition (PVD), atomic layer deposition (ALD), chemical vapor deposition (CVD) or other technique. Alternatively, the rewiring layer 500 may be formed using another other suitable known method.

The rewiring layer 500 may include a rewiring line and a solder pad (I/O pad) electrically connected to the rewiring line. The rewiring layer 500 is provided to rearrange the electrical connection of the second interconnection structure 220 (and hence of the signal processing chip 200, the DRAM chip 600 and the pixel circuit substrate 100) according to the design requirements. The solder pad electrically connected to the rewiring line may be used to connect the rewiring layer to a signal or device outside the package module for processing or control of electrical signals transmitted from the rewiring line.

As a result of the first to fifth steps in the method according to this embodiment, the signal processing chip 200 and the DRAM chip 600 are bonded to the first surface 100a of the pixel circuit substrate 100, and every two of the three are interconnected. The DRAM chip 600 may serve as a cache for storing output data from the readout circuit and outputting the stored data to the signal processing chip 200 at a rate compatible with an operating rate of the signal processing chip 200. In imaging applications of the resulting CMOS image sensor package module, this allows for faster processing of the transmitted data and digital image signals and higher image quality. Additionally, bonding the signal processing chip 200 and the DRAM chip 600 to the pixel circuit substrate 100 provides a larger design margin for the pixel array substrate 100, helping in overall miniaturization of the package module. Compared with wafer-level bonding, the bonded signal processing chip tends to be more computationally powerful and thus favorable to image quality, and the bonded arrangement is simpler and allows discarding any defective one of chips sliced from a single wafer.

In an embodiment of the present invention, there is also provided an imaging device incorporating a CMOS image sensor package module fabricated in accordance with the present invention. The imaging device may be any of various electronics such as miniature cameras, digital cameras, and miniature camera-equipped mobile phones, tablets, notebook computers, smart glasses, digital helmets and monitors. Incorporating the CMOS image sensor package module consistent with the present invention allows the imaging device have a compact size and good image quality.

The method and device embodiments disclosed herein are described in a progressive manner, with the description of each succeeding embodiment focusing on its differences from one or more preceding embodiments, and reference may be made therebetween whenever appropriate.

The foregoing description merely explains and illustrates some preferred embodiments of the present invention and is not intended to limit its scope in any sense. In light of the teachings disclosed above, any person of skill in the art may make various changes and modifications to the disclosed embodiments without departing from the scope of the present invention. Accordingly, any and all such simple changes, equivalent variations and modifications made to the above embodiments in light of the foregoing teachings without departing from the scope of the present invention are intended to fall within the scope.

1. A CMOS image sensor package module, comprising:
a pixel circuit substrate comprising a photosensitive zone and a readout circuit zone, wherein the photosensitive zone is provided with a pixel array of the CMOS image sensor and the readout circuit zone is provided with a readout circuit, the readout circuit having circuit interconnection terminals, the pixel circuit substrate having a first surface and a second surfaces opposing the first surface;
a bonding layer disposed on the first surface;
a signal processing chip and a DRAM chip which are arranged side by side on the bonding layer, wherein: the signal processing chip has a first connection terminal and a second connection terminal both facing the first surface; and the DRAM chip has a third connection terminal and a fourth connection terminal both facing the first surface;
a first interconnection structure that electrically connects the first and third connection terminals, wherein the first interconnection structure comprises a first connecting bump and a second connecting bump that are embedded in the bonding layer, and wherein the first connecting bump is brought into electrical contact with the first connection terminal, the second connecting bump brought into electrical contact with the third connection terminal, the first connecting bump brought into electrical connection to the second connecting bump;
a second interconnection structure disposed in the pixel circuit substrate and in the bonding layer so as to come into electrical connection to each of the circuit interconnection terminal, the second connection terminal and the fourth connection terminal; and
a rewiring layer disposed on the second surface, wherein the rewiring layer is electrically connected to the second interconnection structure.

2. The CMOS image sensor package module of claim 1, wherein the first interconnection structure further comprises an interconnection element located on the first surface, wherein the interconnection element electrically connects the first connecting bump to the second connecting bump.

3. The CMOS image sensor package module of claim 2, wherein the interconnection element comprises an interconnection wire and a first solder pad and a second solder pad located on opposing ends of the interconnection wire, wherein the first solder pad is connected to the first connection terminal via the first connecting bump, the second solder pad connected to the third connection terminal via the second connecting bump; or
wherein the interconnection element comprises an interconnection wire; and the interconnection wire is connected to the first connection terminal via the first connecting bump at one end and to the third connection terminal via the second connecting bump at the other end.

4. (canceled)

5. The CMOS image sensor package module of claim 1, wherein the first and second connecting bumps are integrated as a single connecting bump extending from the first connection terminal to the third connection terminal.

6. The CMOS image sensor package module of claim 1, wherein the second interconnection structure comprises a first conductive plug disposed in the pixel circuit substrate, wherein the first conductive plug electrically connects the circuit interconnection terminals to the rewiring layer, wherein the circuit interconnection terminal includes a first circuit interconnection terminal and a second circuit interconnection terminal, and wherein the second interconnection structure comprises two first conductive plugs to respectively electrically connect the first and second circuit interconnection terminals to the rewiring layer.

7. (canceled)

8. The CMOS image sensor package module of claim 1, wherein the second interconnection structure comprises a second conductive plug extending through the pixel circuit substrate and the bonding layer, and wherein the second conductive plug electrically connects the second connection terminal to the rewiring layer; or
wherein the second interconnection structure comprises a third conductive plug extending through the pixel circuit substrate and the bonding layer the third conductive plug electrically connects the fourth connection terminal to the rewiring layer.

9. (canceled)

10. The CMOS image sensor package module of claim 1, wherein the signal processing chip and the DRAM chip are arranged on the first surface in the readout circuit zone.

11. The CMOS image sensor package module of claim 1, wherein the rewiring layer comprises a rewiring line and a solder pad electrically connected to the rewiring line.

12. The CMOS image sensor package module of claim 1, further comprising an encapsulation layer disposed on the first surface and a dummy chip located on the bonding layer, wherein the encapsulation layer covers the signal processing chip and the DRAM chip, and fills up any gap present on the surface, wherein the encapsulation layer also covers the dummy chip, wherein light is configured to be incident on the pixel array from the second surface, and wherein the dummy chip is arranged above the first surface in the photosensitive zone.

13. (canceled)

14. (canceled)

15. The CMOS image sensor package module of claim 1, wherein the CMOS image sensor is a back-illuminated CMOS image sensor.

16. The CMOS image sensor package module of claim 1, wherein the bonding layer comprises an adhesive material.

17. An imaging device comprising a CMOS image sensor package module, wherein the CMOS image sensor package module comprises:
a pixel circuit substrate comprising a photosensitive zone and a readout circuit zone, wherein the photosensitive zone is provided with a pixel array of the CMOS image sensor and the readout circuit zone is provided with a readout circuit, the readout circuit having circuit interconnection terminals, the pixel circuit substrate having a first surface and a second surfaces opposing the first surface;
a bonding layer disposed on the first surface;
a signal processing chip and a DRAM chip which are arranged side by side on the bonding layer, wherein: the signal processing chip has a first connection terminal and a second connection terminal both facing the first surface; and the DRAM chip has a third connection terminal and a fourth connection terminal both facing the first surface;
a first interconnection structure that electrically connects the first and third connection terminals, wherein the first interconnection structure comprises a first connecting bump and a second connecting bump that are embedded in the bonding layer, and wherein the first connecting bump is brought into electrical contact with the first connection terminal, the second connecting bump brought into electrical contact with the third connection terminal, the first connecting bump brought into electrical connection to the second connecting bump;
a second interconnection structure disposed in the pixel circuit substrate and in the bonding layer so as to come into electrical connection to each of the circuit interconnection terminal, the second connection terminal and the fourth connection terminal; and
a rewiring layer disposed on the second surface, wherein the rewiring layer is electrically connected to the second interconnection structure.

18. A method for forming a CMOS image sensor package module, comprising:
providing a pixel circuit substrate, a signal processing chip and a DRAM chip, wherein the pixel circuit substrate comprises a photosensitive zone and a readout circuit zone, wherein the photosensitive zone is provided with a pixel array of the CMOS image sensor and the readout circuit zone is provided with a readout circuit, the readout circuit having circuit interconnection terminals, the pixel circuit substrate having a first surface and a second surface opposing the first surface, the signal processing chip having a first connection terminal and a second connection terminal, the DRAM chip having a third connection terminal and a fourth connection terminal;
forming a bonding layer on the first surface and bonding the signal processing chip and the DRAM chip to the bonding layer in such a manner that each of the first, second, third and fourth connection terminals faces the first surface;
forming a first interconnection structure to electrically connect the first and third connection terminals, wherein the first interconnection structure comprises a first connecting bump and a second connecting bump that are embedded in the bonding layer, and wherein the first connecting bump is brought into electrical contact with the first connection terminal, the second connecting bump brought into electrical contact with the third connection terminal, the first connecting bump brought into electrical connection to the second connecting bump;
forming a second interconnection structure disposed in the pixel circuit substrate and in the bonding layer so as to come into electrical connection to each of the circuit interconnection terminals, the second connection terminal and the fourth connection terminal; and
forming a rewiring layer on the second surface, wherein the rewiring layer is electrically connected to the second interconnection structure.

19. The method for forming a CMOS image sensor package module of claim 18, further comprising, prior to the formation of the bonding layer, forming an interconnection element on the first surface, wherein the interconnection element electrically connects the first connecting bump to the second connecting bump, and wherein the bonding layer is provided with an opening, in which areas of the interconnection element aligned respectively with the first and third connection terminals are exposed.

20. (canceled)

21. The method for forming a CMOS image sensor package module of claim 19, wherein the first and second connecting bumps are formed using a process comprising:
placing the pixel circuit substrate with the bonding layer, the signal processing chip and the DRAM chip in an electroless plating solution containing metal ions and a reducing agent; and
forming the first and second connecting bumps in the opening after elapse of a predetermined period of time, wherein the first connecting bump covers the area of the interconnection element aligned with the first connection terminal and thus being electrically connected to the first connection terminal, the second connecting bump covering the area of the interconnection element aligned with the third connection terminal and thus being electrically connected to the third connection terminal,
wherein the interconnection element is exposed in the opening, and wherein the first and second connecting bumps are integrated as a single connecting bump extending from the first connection terminal to the third connection terminal.

22. (canceled)

23. The method for forming a CMOS image sensor package module of claim 18, wherein the first and second connecting bumps are formed of a material including one or more of copper, nickel, zinc, tin, silver, gold, tungsten and magnesium.

24. The method for forming a CMOS image sensor package module of claim 18, wherein the formation of the second interconnection structure comprises forming a plurality of conductive plugs through forming holes by performing an etching process on the second surface and through filling the holes.

25. The method for forming a CMOS image sensor package module of claim 24, wherein the plurality of conductive plugs include a first conductive plug, wherein the first conductive plug is disposed in the pixel circuit substrate and electrically connects the circuit interconnection terminals to the rewiring layer; or
wherein the plurality of conductive plugs include a second conductive plug, wherein the second conductive plug extends through each of the pixel circuit substrate and the bonding layer, and electrically connects the second connection terminal to the rewiring layer; or
wherein the plurality of conductive plugs include a third conductive plug, and wherein the third conductive plug extends through each of the pixel circuit substrate and the bonding layer, and electrically connects the fourth connection terminal to the rewiring layer.

26. (canceled)

27. (canceled)

28. The method for forming a CMOS image sensor package module of claim 18, further comprising, subsequent to the formation of the first interconnection structure and prior to the formation of the second interconnection structure, forming an encapsulation layer on the first surface, wherein the encapsulation layer covers the signal processing chip and the DRAM chip, and fills up any gap present on the surface.

29. The method for forming a CMOS image sensor package module of claim 28, further comprising, subsequent to the formation of the bonding layer, bonding a dummy chip to the bonding layer, wherein the encapsulation layer also covers the dummy chip, wherein the signal processing chip and the DRAM chip are bonded in the readout circuit zone, wherein light is configured to be incident on the pixel array from the second surface, and wherein the dummy chip is bonded in the photosensitive zone.

30. (canceled)
